(19) United States
(12) Patent Application Publication
(10) Pub. No.: US 2016/0155691 A1
(43) Pub. Date: Jun. 2, 2016

(54) MULTI-LAYERED CIRCUIT DEVICE

(71) Applicants: HYUNDAI MOTOR COMPANY, Seoul (KR); Hyundai Mobis Co., Ltd., Seoul (KR)

(72) Inventors: Jin Ho NA, Suwon-si (KR); Seong Yeon HAN, Yongin-si (KR)

(21) Appl. No.: 14/673,772

(22) Filed: Mar. 30, 2015

(30) Foreign Application Priority Data
Dec. 2, 2014 (KR) 10-2014-0170375

(51) Int. Cl. H01L 23/498; H01L 33/62; H01L 25/075

(52) U.S. Cl. CPC H01L 23/49822; H01L 23/49838; H01L 25/0753; H01L 33/62

(57) ABSTRACT

A multi-layered circuit device includes multiple electrode lines arranged in a plurality of layers. Also included are multiple elements. At least one of the electrode lines is connected to at least one of the elements. An insulator is disposed in between the multiple electrode lines to prevent current flow between the electrode lines.

### CROSS REFERENCE TO RELATED APPLICATION

The present application claims the benefit of priority to Korean Patent Application Number 10-2014-0170375 filed on Dec. 2, 2014, the entire contents of which application are incorporated herein for all purposes by this reference.

### TECHNICAL FIELD

The present invention relates generally to a multi-layered circuit device and, more particularly, to a multi-layered circuit device for connecting electrode lines to isolated elements.

### BACKGROUND

Multiple elements may be arranged on a circuit, and degree of integration of the elements varies according to circuit size and the number of elements on the circuit.

In the case of a LED chip, a plurality of LED chips may be closely arranged on a circuit. As occasion demands, multiple chips may be arranged to have multiple rows of a matrix structure to increase density of emitting lights.

When the multiple chips are arranged in a multi-row chip arrangement as mentioned above, there may be isolated chips surrounded by other chips. In this case, to supply power, conventional methods connect electrodes to the isolated chips using gold wires.

However, as shown in FIG. 1, in the case of connecting electrodes using gold wires, as the gold wires 30 cross over the upper section of chips 10 located in an outer side and connect to isolated chips 20, the gold wires may affect light distribution of the chips 10 located in the outer side, thus causing decrease in total amount of light.

The foregoing is intended merely to aid in the understanding of the background of the present invention, and is not intended to mean that the present invention falls within the purview of the related art that is already known to those skilled in the art.

### SUMMARY

Accordingly, the present disclosure has been made to address the above problems and an object of the present invention is to provide a multi-layered circuit device, when multiple elements are closely arranged, to connect electrodes to isolated elements.

A multi-layered circuit device includes multiple electrode lines, arranged in a plurality of layers. Also included are multiple elements, wherein at least one of the electrode lines is connected to at least one of the elements. An insulator is disposed between the multiple electrode lines to prevent current flow between the multiple electrode lines.

In certain embodiments, the electrode lines may electrically conduct positive electrodes.

In certain embodiments, the multiple elements may be arranged from one side of the device to the other side of the device in an order. The electrode lines may layered according to the order of the elements, so that a first electrode line in the topmost layer of the plurality of layers is connected to an outermost element on the one side of the device, and the remaining electrode lines may be layered according to the order of the elements to which they are connected.

In certain embodiments, a ground line, connected to each of the elements and arranged so as to be layered with respect to the multiple electrode lines, may be further included.

In certain embodiments, the ground line may be separated from the electrode lines by a predetermined gap, and may provide a common ground for each of the elements.

A first electrode line may be connected to a first element. If an additional element is located on a path of the first electrode line, the first electrode line may be layered with respect to an additional electrode line connected to the additional element. In certain embodiments, the first electrode line connected to the first element may be layered below the additional electrode line connected to the additional element.

According to the multi-layered circuit device as described above, each electrode line is arranged such that the lines do not come into contact with each other. Also, in certain embodiments, as factors affecting light distribution of LED chips may be removed, quality of light distribution may be improved.

Additionally, as there is no concern that electrode connecting lines are broken, stability of a product may be improved.

### BREIF DESCRIPTION OF THE DRAWINGS

The above and other objects, features and other advantages of the present invention will be more clearly understood from the following detailed description taken in conjunction with the accompanying drawings, in which:

FIG. 1 is a plan view illustrating a method of connecting electrode using gold wires according to conventional art;

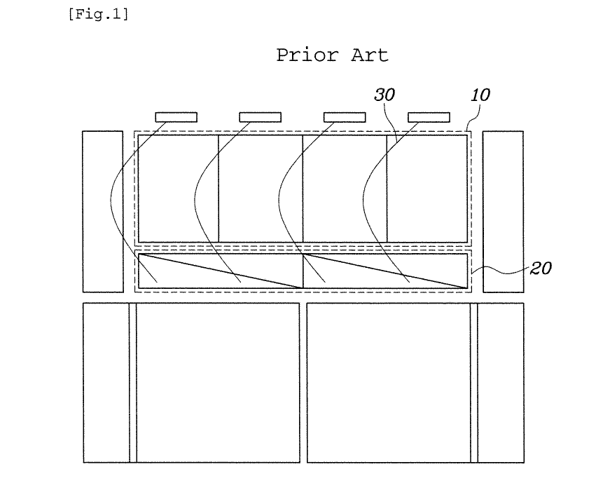

FIG. 2 is a side view of a multi-layered circuit device according to an embodiment of the present invention, with the circled portion shown enlarged in greater detail; and

FIG. 3 is a cross sectional view of the multi-layered circuit device taken along line A-A in FIG. 2, showing more detail than in FIG. 2.

### DETAILED DESCRIPTION

Hereinafter, a multi-layered circuit device according to an embodiment of the present invention will be described referring to the accompanying drawings.

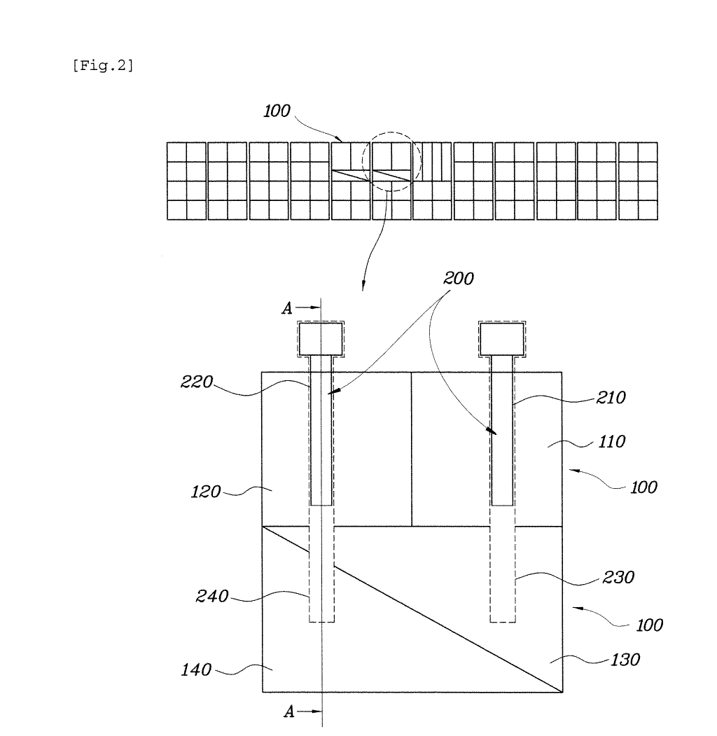

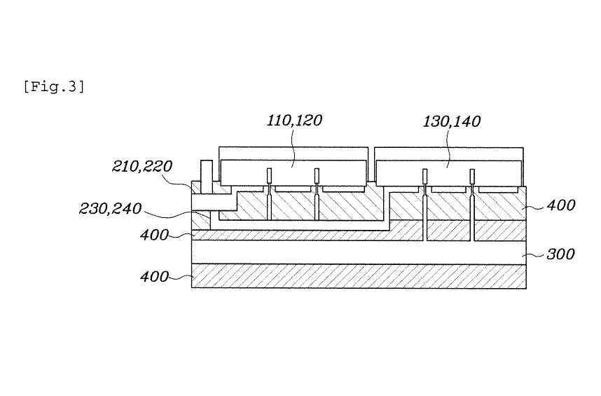

FIG. 2 is a side view of a multi-layered circuit device according to an embodiment of the present invention, with the circled portion shown enlarged in greater detail. FIG. 3 is a cross sectional view of A-A shown in FIG. 2 and is more detailed than in FIG. 2. A multi-layered circuit device according to an embodiment of the present invention includes a plurality of electrode lines 200, which are connected to a plurality of elements 100, respectively, and are arranged so as to be layered with respect to each other; and insulators 400 disposed in between the multiple electrode lines 200 to prevent current flow between each of the electrode lines 200.

In the embodiment, the elements 100 may include various electrical components that may be installed on a circuit, such as a transistor, a semiconductor, and the like. In certain embodiments, the element may be a LED chip. A LED chip emits light from an upper side. Accordingly, in case of a conventional method of connecting electrodes using gold wires, gold wires cross over the upper side of the adjacent LED chips, thus causing shadowing or unbalanced distribution of light. However, the present invention arranges each electrode line to run along the bottom of each element 100, for example, to the bottom of each LED chip, and thus unbalanced distribution of light is resolved and unobstructed lighting may be obtained.

On the other hand, it is desirable that the electrode line 200 is a line electrically conducting positive (+) electrodes. Also, separated from the electrode lines, a ground line 300, which is connected to each element 100 and arranged so as to be layered with respect to the multiple electrode lines 200, may be further included.

In certain embodiments, one electrode line 200 is connected to one element 100. However, in certain embodiments, when controlling multiple elements or applying power to multiple elements 100 through one electrode line, it is possible to connect one electrode line with multiple elements 100. In certain embodiments, multiple electrode lines may be connected to one element 100.

As shown in FIG. 2, first and second elements 110 and 120 located in the outermost of the circuit may be directly connected to electrode lines 200. However, it is not easy to connect electrodes to isolated third and fourth elements 130 and 140, which are surrounded by multiple elements 100, if the electrodes do not pass the first and second elements 110 and 120 in the outermost of the circuit.

Consequently, as shown in FIG. 3, the multiple electrode lines 200 are configured as follows. When an additional element 100 is located on the path of the electrode line 200, it is desirable that the electrode line 200 is connected to a corresponding element layered with respect to an additional electrode line connected to the additional element 100. For example, in FIG. 2, as a third element 130 and a fourth element 140 are located in the inner portion of the circuit in comparison with a first element 110 and a second element 120, the third and fourth elements are isolated. Accordingly, to connect electrode lines 200 to the third and fourth elements, a first electrode line 210 and a second electrode line 220, respectively corresponding to the first element 110 and the second element 120, may be layered with respect to a third electrode line 230 and a fourth electrode line 240, respectively corresponding to the third element 130 and the fourth element 140.

In this case, the third electrode line 230 or fourth electrode line 240, passing the first element 110 or second element 120, may be arranged on a lower layer than the first electrode line 210 or second electrode line 220. Alternatively, in certain embodiments, the third and fourth electrode lines 230 and 240 may be arranged on a higher layer than the first and second electrode lines 110 and 120. In certain embodiments, if there are a fifth electrode line (not illustrated) or a sixth electrode line (not illustrated), passing the third element 130 or fourth element 140 and connected to a fifth element (not illustrated) or a sixth element (not illustrated), the fifth and sixth electrode lines may be arranged so as to be layered below the third electrode line 230 or fourth electrode line 240. Alternatively, in certain embodiments, the fifth and sixth electrode lines may be layered above the first and second electrode lines 110 and 120. That may minimize the length of each of the electrode lines 200 and prevent confusion between the electrode lines 200.

More preferably, as being arranged in the direction from the first element 110 and second element 120 to the third element 130 and fourth element 140, when the multiple elements 100 are sequentially arranged from one side to the other side, electrode lines 200 that are connected to the elements located on the outermost of the one side, for example, the first electrode line 210 and second electrode line 220, are arranged on the topmost layer. Then, the remaining electrode lines including the third electrode line 230 and fourth electrode line 240 are continuously layered from top to bottom to be sequentially connected to the corresponding elements.

The above description is an exemplary embodiment, and electrode lines 200 connected to each element may be variously layered with a predetermined gap, individually. Also, in the present embodiment, it is desirable that every layer of each electrode line 200 is a relative position to the other electrode line 200. A gap between neighboring layers of electrode lines 200 may be variously set according to material, a thickness, and a property of an insulator 400, or according to designer's intention. A gap between neighboring layers of electrode lines 200 may be set to have the same width or set to have a different width.

On the other hand, the ground line 300 is layered separately with respect to the electrode line 200 with a predetermined gap. Also, it is desirable that each element share a common ground. Not contacting with the electrode lines 200, the ground line 300 may be arranged on the topmost layer or bottommost layer, or it may be arranged on the layer between the electrode lines 200.

For example, the ground line 300 may be arranged on the bottommost layer under the layers of electrode line 200. Accordingly, passing the stacked insulators 400, the ground line 300 may be electrically connected to each element 100 on the upper layers. However, that is just an embodiment, and the location of the ground line 300 may be variously set.

Also, the insulator 400 is made of an electrically insulating material such as resinoid, rubber, or the like. The insulator 400 may be disposed in between electrode lines 200 or in between an electrode line and ground line, or may wrap the electrode lines or the ground line, to prevent current flow between electrode lines 200 or between electrode lines 200 and the ground line 300.

Also, it is desirable that the insulator is a material that may support the whole circuit including the elements 100, electrode lines 200, and the ground line as one module.

According to the multi-layered circuit device as described above, connecting electrodes is possible without gold wires by arranging each electrode line such that they do not come into contact with each other. Also, as factors affecting light distribution of LED chips are removed, quality in light distribution may be improved.

Additionally, as there is no concern that electrode connecting lines are broken, stability of a product may be improved.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A multi-layered circuit device, comprising:
multiple electrode lines, arranged respectively in a plurality of layers;
multiple elements, wherein at least one of the electrode lines is connected to at least one of the elements; and
an insulator disposed between the multiple electrode lines in order to prevent current flow between the multiple electrode lines.

2. The device of claim 1, wherein the electrode lines electrically conduct positive electrodes.

3. The device of claim 1, wherein the multiple elements are arranged from one side of the device to the other side of the device in an order, and the electrode lines are layered according to the order of the elements, so that a first electrode line in the topmost layer of the plurality of layers is connected to an outermost element on the one side of the device, and remaining electrode lines are layered according to the order of the elements to which they are connected.

4. The device of claim 1, further comprising a ground line connected to each of the elements and arranged so as to be layered with respect to the multiple electrode lines.

5. The device of claim 4, wherein the ground line is separated from the electrode lines by a predetermined gap, and provides a common ground for each of the elements.

6. The device of claim 1, wherein a first electrode line is connected to a first element, an additional element is located on a path of the first electrode line, and the first electrode is layered with respect to an additional electrode line connected to the additional element.

7. The device of claim 6, wherein the first electrode line is layered below the additional electrode line connected to the additional element.
